(19) United States
(12) Patent Application Publication
(10) Pub. No.: US 2026/0314085 A1
(43) Pub. Date: Oct. 8, 2026

(54) INTEGRATED CHIP AND METHOD OF MANUFACTURING THE SAME

(71) Applicant: Taiwan Semiconductor Manufacturing Company, Ltd., Hsinchu (TW)

(72) Inventors: Kuo-Chin Huang, Yilan City (TW); Tung-Hsiung Tseng, Pingtung City (TW); Tzu-Jui Wang, Fengshan City (TW); Chen-Jong Wang, Hsin-Chu (TW); Dun-Nian Yaung, Taipei City (TW)

(21) Appl. No.: 19/171,755

(22) Filed: Apr. 7, 2025

(51) Int. Cl. H10F 30/225; H10F 71/00; H10F 77/14; H10F 77/20

(52) U.S. Cl. CPC H10F 30/225; H10F 71/133; H10F 77/14; H10F 77/241

(57) ABSTRACT

An integrated chip includes a semiconductor substrate. The substrate includes a bulk region having a first doping type. A first doped region is in the substrate along a first side of the substrate has a second doping type, different than the first doping type. The first doped region forms a first terminal of a single photon avalanche diode (SPAD). A conductive layer extends from a second side of the substrate toward the first side of the substrate and laterally surrounds the SPAD. The integrated chip includes a dielectric layer between a first sidewall of the conductive layer and a first sidewall of the substrate. The integrated chip includes a second terminal of the SPAD along the second side of the substrate. The second terminal has the first doping type and is coupled to the conductive layer along an upper surface and a second sidewall of the conductive layer.

### BACKGROUND

Integrated circuits (ICs) with complementary metal-oxide-semiconductor (CMOS) image sensors are used in a wide range of modern-day electronic devices, such as, for example, cameras and cell phones. Some CMOS image sensors are based on avalanche photodiodes (APD) and single-photon avalanche photodiodes (SPAD). Some types of CMOS image sensors include front-side illuminated (FSI) image sensors and back-side illuminated (BSI) image sensors.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIG. 1 illustrates a cross-sectional view of some embodiments of an image sensor integrated chip comprising a single photon avalanche diode (SPAD) in a semiconductor substrate.

FIG. 2 illustrates an enlarged cross-sectional view of a portion the image sensor integrated chip of FIG. 1.

FIG. 3 illustrates a top view and FIG. 4 illustrates top view of some embodiments of the image sensor integrated chip of FIG. 1.

FIG. 5 illustrates a top view and FIG. 6 illustrates a top view of some other embodiments of the image senor integrated chip of FIG. 1.

FIG. 7 illustrates a cross-sectional view of some embodiments of the image sensor integrated chip of FIG. 1.

FIG. 8 illustrates a cross-sectional view of some embodiments of the image sensor integrated chip of FIG. 1.

FIG. 9 illustrates a top view of some embodiments of the image sensor integrated chip of FIG. 8.

FIG. 10 and FIG. 11 illustrate cross-sectional views of some other embodiments of the image sensor integrated chip of FIG. 1.

FIG. 12 illustrates a cross-sectional view and FIG. 13 illustrates a top view of some embodiments of the image senor integrated chip of FIG. 1.

FIG. 14 illustrates a cross-sectional view and FIG. 15 illustrates a top view of some other embodiments of the image senor integrated chip of FIG. 1.

FIG. 16 illustrates a cross-sectional view and FIG. 17 illustrates a top view of some other embodiments of the image senor integrated chip of FIG. 1.

FIGS. 18-29 illustrate cross-sectional views of some embodiments of a method of forming an image sensor integrated chip comprising a SPAD in a semiconductor substrate.

FIG. 30 illustrates a flow diagram of some embodiments of a method of forming an image sensor integrated chip comprising a SPAD in a semiconductor substrate.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

An image sensor integrated chip includes a single photon avalanche diode (SPAD) in a semiconductor substrate. A bulk region of the semiconductor substrate has a first doping type. A first doped region is in the semiconductor substrate along a front side of the semiconductor substrate. The first doped region has a second doping type different than the first doping type. The first doped region forms a first terminal (e.g., cathode) of the SPAD. A second doped region having the first doping type is in the semiconductor substrate. The second doped region forms a second terminal (e.g., anode) of the SPAD.

In some chips, the second doped region is disposed along the front side of the semiconductor substrate and laterally spaced from the first doped region. In such chips, a distance between the first doped region and the second doped region is small. Thus, a strength of the electric field along the sides of the first doped region is high. Consequently, a magnitude of the breakdown voltage of the SPAD can be reduced and thus a likelihood of the SPAD experiencing premature breakdown is increased. Further, a dark count rate of the SPAD can be increased. Furthermore, a jitter of the SPAD can be worsened.

In various embodiments of the present disclosure, the second doped region is disposed along a back side of the semiconductor substrate, opposite the front side, to improve a performance of the image sensor integrated chip. For example, by disposing the second doped region along the back side of the semiconductor substrate, the distance between the first doped region and the second doped region can be increased. Thus, the strength of the electric field along the sides of the first doped region can be reduced. As a result, the magnitude of the breakdown voltage of the SPAD can be increased and thus a likelihood of the SPAD experiencing premature breakdown can be reduced. Further, the dark count rate of the SPAD can be reduced and the jitter of the SPAD can be improved.

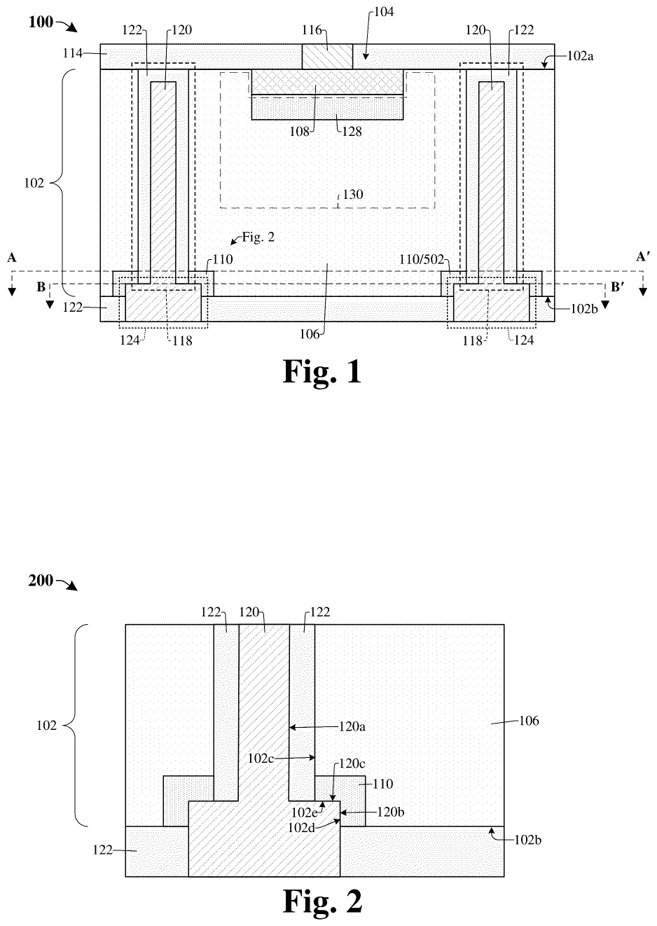

FIG. 1 illustrates a cross-sectional view 100 of some embodiments of an image sensor integrated chip comprising a single photon avalanche diode (SPAD) 104 in a semiconductor substrate 102. FIG. 2 illustrates an enlarged cross-sectional view 200 of a portion the image sensor integrated chip of FIG. 1.

Referring to FIG. 1 and FIG. 2, the semiconductor substrate 102 includes a bulk region 106 having a first doping type (e.g., p type). A first doped region 108 is in the semiconductor substrate 102 along a front side 102a of the semiconductor substrate 102. The first doped region 108 has a second doping type (e.g., n type) different than the first doping type. The first doped region 108 forms a first terminal (e.g., a cathode) of the SPAD 104.

A second doped region 110 is in the semiconductor substrate 102 along a back side 102b of the semiconductor substrate 102. The second doped region 110 has the first doping type. The second doped region 110 forms a second terminal (e.g., an anode) of the SPAD 104.

Because the second doped region 110 is along the back side 102b of the semiconductor substrate 102, the distance between the first doped region 108 and the second doped region 110 can be increased. Thus, the strength of the electric field along the sides of the first doped region can be reduced. As a result, the magnitude of the breakdown voltage of the SPAD 104 can be increased. Thus, a likelihood of the SPAD 104 experiencing premature breakdown is reduced. Further, a dark count rate of the SPAD 104 can be reduced and a jitter of the SPAD 104 can be improved.

A dielectric layer 114 is on the front side 102a of semiconductor substrate 102. A contact 116 is between sidewalls of dielectric layer 114 and contacts the first doped region 108 along the front side 102a of the semiconductor substrate 102. Contact 116 forms an electrode of the first terminal of the SPAD 104.

A deep trench isolation (DTI) structure 118 extends from the back side 102b of the semiconductor substrate 102 toward the front side 102a of the semiconductor substrate 102 and laterally surrounds the SPAD 104 to electrically and/or optically isolate the SPAD 104 from neighboring SPADs (not shown). The DTI structure 118 includes a conductive core formed by a conductive layer 120. The DTI structure 118 includes a dielectric liner formed by a dielectric layer 122. The dielectric liner is between the conductive core and the semiconductor substrate 102. For example, dielectric layer 122 extends between a sidewall 120a of conductive layer 120 and a sidewall 102c of the semiconductor substrate 102.

A conductive grid structure 124 is under the DTI structure 118 and coupled to the conductive core of the DTI structure 118. The conductive grid structure 124 is formed by conductive layer 120. The conductive grid structure 124 is also coupled to the second doped region 110. For example, the semiconductor substrate 102 has a sidewall 102d and a lower surface 102e extending from a top of sidewall 102d to a bottom of sidewall 102c. The second doped region 110 extends along sidewall 102d and lower surface 102e of the semiconductor substrate 102. Further, conductive layer 120 has a sidewall 120b and an upper surface 120c extending from a top of sidewall 120b to a bottom of sidewall 120a. Sidewall 120b contacts sidewall 102d and upper surface 120c contacts lower surface 102e. Thus, the second doped region 110 is coupled to conductive layer 120 along sidewall 120b and upper surface 120c. The conductive grid structure 124 and conductive core of the DTI structure 118 form an electrode of the second terminal of the SPAD 104.

Dielectric layer 122 is on the back side 102b of the semiconductor substrate 102, and the conductive grid structure 124 (e.g., conductive layer 120) is between sidewalls of dielectric layer 122 along the back side 102b.

A third doped region 128 (e.g., an avalanche region) having the first doping type is under the first doped region 108 and abuts the first doped region 108. A p-n junction is formed at the interface between the first doped region 108 and the third doped region 128. A depletion region 130 is formed around the first doped region 108.

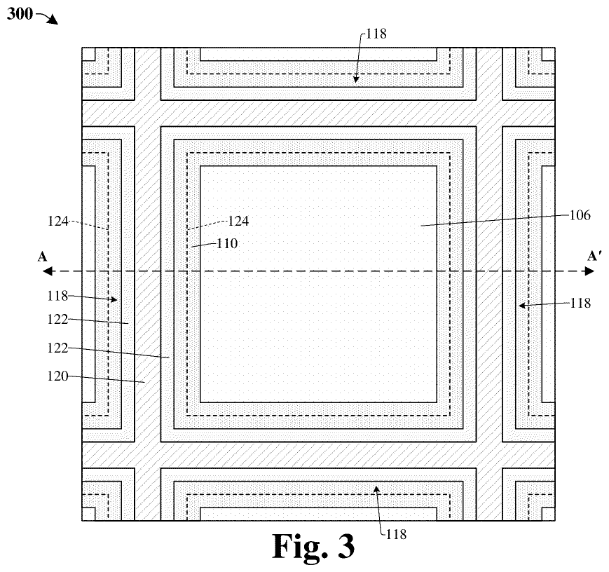

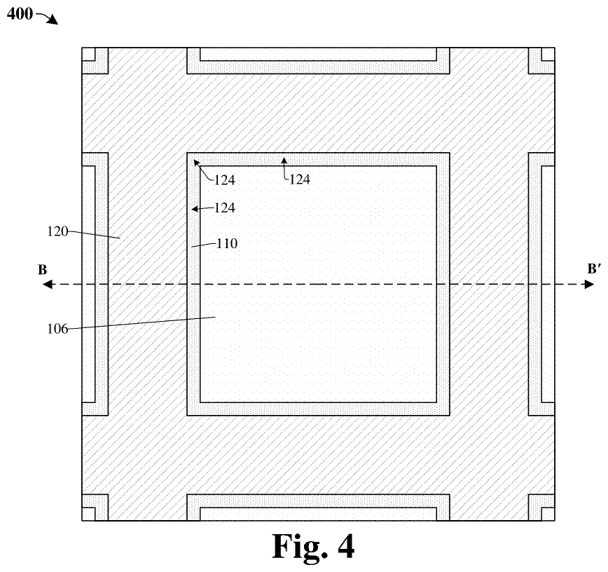

FIG. 3 illustrates a top view 300 and FIG. 4 illustrates top view 400 of some embodiments of the image sensor integrated chip of FIG. 1. In some embodiments, section line A-A′ of FIG. 3 corresponds to section line A-A′ of FIG. 1. In some embodiments, section line B-B′ of FIG. 4 corresponds to section line B-B′ of FIG. 1.

The conductive grid structure 124 is under the DTI structure 118 at the “crossroads” of the DTI structure 118 and between the “crossroads” of the DTI structure 118. Further, the second doped region 110 has a ring-shaped top layout. The second doped region 110 laterally surrounds a portion of the bulk region 106 in a closed, ring-shaped path. The second doped region 110 extends along sidewalls of the dielectric layer 122 (e.g., sidewalls of the DTI structure 118) and sidewalls of the conductive layer 120 (e.g., sidewalls of the conductive grid structure 124) in the ring-shaped path.

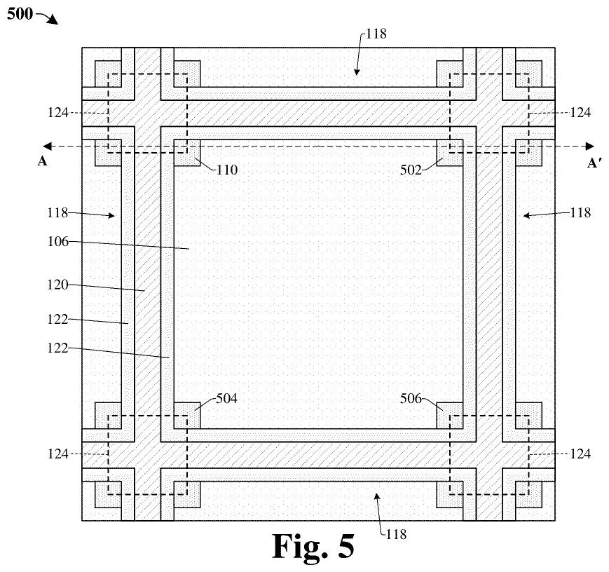

FIG. 5 illustrates a top view 500 and FIG. 6 illustrates a top view 600 of some other embodiments of the image senor integrated chip of FIG. 1. In some embodiments, section line A-A′ of FIG. 5 corresponds to section line A-A′ of FIG. 1. In some embodiments, section line B-B′ of FIG. 6 corresponds to section line B-B′ of FIG. 1.

The conductive grid structure 124 is under the DTI structure 118 at the “crossroads” of the DTI structure 118, but not between the “crossroads” of the DTI structure 118. In addition, the SPAD 104 further includes a fourth doped region 502, a fifth doped region 504, and a sixth doped region 506 having the first doping type disposed in the semiconductor substrate 102 along the back side 102b. The second doped region 110, the fourth doped region 502, the fifth doped region 504, and the sixth doped region 506 are laterally spaced apart and disposed at the corners of the SPAD 104. The fourth doped region 502, the fifth doped region 504, and the sixth doped region 506 further form the second terminal of the SPAD 104. The conductive grid structure 124 and conductive core of the DTI structure 118 (e.g., conductive layer 120) are coupled to the fourth doped region 502, the fifth doped region 504, and the sixth doped region 506.

In some embodiments, the first doping type is p type and the second doping type is n type. In such embodiments, the first doped region 108 forms the cathode of the SPAD 104 and the second doped region 110 forms the anode of the SPAD 104. In some other embodiments, the first doping type is n type and the second doping type is p type. In such embodiments, the first doped region 108 forms the anode of the SPAD 104 and the second doped region 110 forms the cathode of the SPAD 104.

In some embodiments, the second doped region 110 (and doped regions 502, 504, 506) have greater doping concentrations than the bulk region 106. For example, in some embodiments, the bulk region 106 has p doping and the second doped region 110 (and doped regions 502, 504, 506) have p+ doping. In some embodiments, the first doped region 108 has a high doping concentration (e.g., n+ doping).

In some embodiments, the semiconductor substrate 102 comprises silicon or some other suitable material. In some embodiments, dielectric layer 114 comprises silicon oxide or some other suitable material. In some embodiments, dielectric layer 122 comprises silicon oxide or some other suitable material. In some embodiments, conductive layer 120 comprises copper, tungsten, aluminum, tantalum, titanium, or some other suitable material. In some embodiments, contact 116 comprises copper, tungsten, aluminum, tantalum, titanium, or some other suitable material.

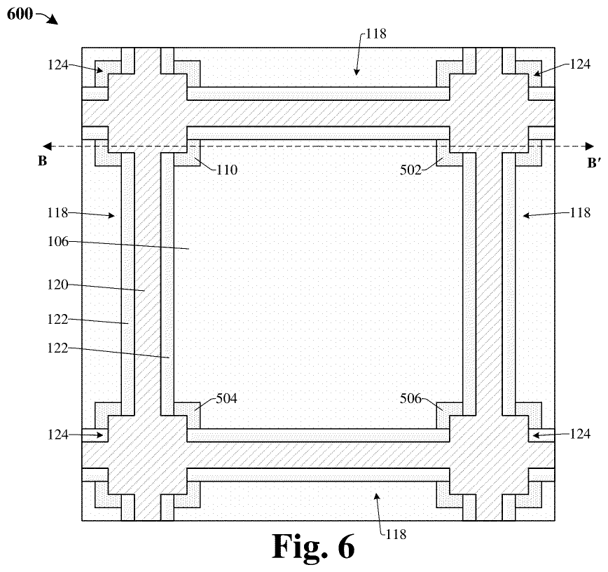

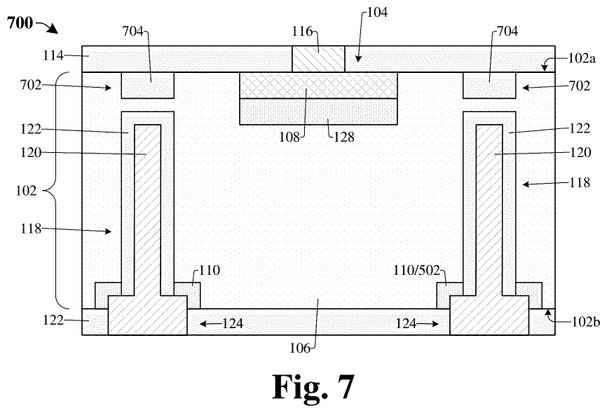

FIG. 7 illustrates a cross-sectional view 700 of some embodiments of the image sensor integrated chip of FIG. 1 in which a shallow trench isolation (STI) structure 702 is over the DTI structure 118.

The STI structure 702 is disposed along the front side 102a of the semiconductor substrate 102 and laterally surrounds the SPAD 104. The STI structure 702 is formed by a dielectric layer 704. The STI structure 702 is directly over the DTI structure 118. For example, a bottom surface of dielectric layer 704 is directly over a top surface of dielectric layer 122. In some embodiments, the STI structure 702 is spaced over the DTI structure 118 so that a portion of the bulk region 106 is directly between the STI structure 702 and the DTI structure 118. In some other embodiments (not shown), the STI structure 702 is on the DTI structure 118 so that the bottom surface of dielectric layer 704 is in contact with the top surface of dielectric layer 122. In some embodiments, dielectric layer 704 comprises silicon oxide or some other suitable material.

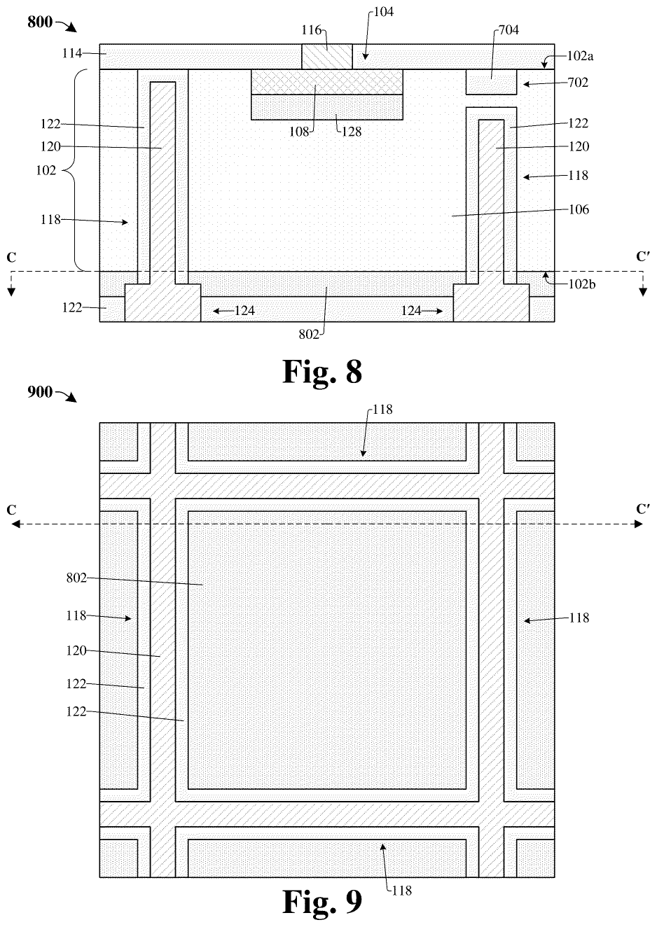

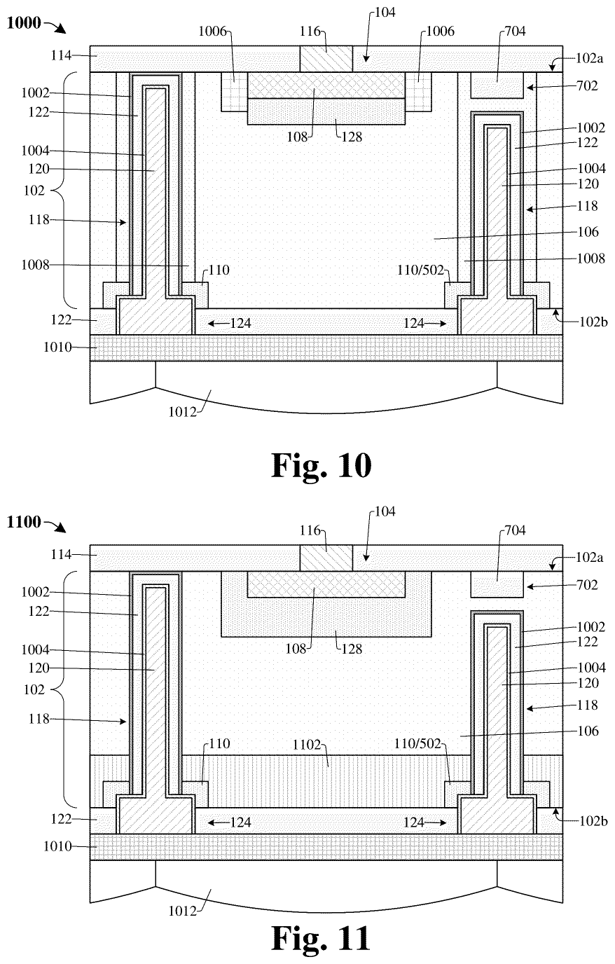

A portion of the STI structure 702 is illustrated in FIG. 8, FIG. 10, and FIG. 11 to illustrate how the STI structure 702 can be included in the embodiments of FIG. 8, FIG. 10, and FIG. 11.

FIG. 8 illustrates a cross-sectional view 800 of some embodiments of the image sensor integrated chip of FIG. 1 in which a semiconductor layer 802 is on the back side 102b of the semiconductor substrate 102. FIG. 9 illustrates a top view 900 of some embodiments of the image sensor integrated chip of FIG. 8. In some embodiments, section line C-C′ of FIG. 9 corresponds to section line C-C′ of FIG. 8.

The semiconductor layer 802 has the first doping type and forms the second terminal of the SPAD 104. The semiconductor layer 802 is coupled to the conductive grid structure 124 and the conductive core of the DTI structure 118. The semiconductor layer 802 covers the back side 102b of the semiconductor substrate 102. In some embodiments, semiconductor layer 802 comprises silicon or some other suitable material. In some embodiments, the semiconductor layer 802 has a greater doping concentration than the bulk region 106 (e.g., the semiconductor layer 802 has p+ doping). The conductive grid structure 124 is not shown in FIG. 9 for simplicity and clarity of illustration.

FIG. 10 illustrates a cross-sectional view 1000 of some other embodiments of the image sensor integrated chip of FIG. 1.

In some embodiments, a dielectric liner layer 1002 lines dielectric layer 122 and further forms the DTI structure 118. Dielectric liner layer 1002 extends between dielectric layer 122 and the semiconductor substrate 102. Dielectric liner layer 1002 extends between dielectric layer 122 and doped region 110. Dielectric liner layer 1002 extends between dielectric layer 122 and dielectric layer 114. In some embodiments, dielectric liner layer 1002 comprises silicon oxide, aluminum oxide, hafnium oxide, tantalum oxide, or some other suitable material.

In some embodiments, a conductive liner layer 1004 (e.g., a glue layer) lines conductive layer 120 and further forms the conductive core of the DTI structure 118 and the conductive grid structure 124. Conductive liner layer 1004 extends between conductive layer 120 and dielectric layer 122. Conductive liner layer 1004 extends between conductive layer 120 and doped region 110 and couples conductive layer 120 to doped region 110. In some embodiments, conductive liner layer 1004 comprises tantalum nitride, titanium nitride, or some other suitable material.

In some embodiments, a doped region 1006 (e.g., a guard ring region) having the second doping type is in the semiconductor substrate 102 along the front side 102a of the semiconductor substrate 102. Doped region 1006 laterally surrounds doped region 108 and doped region 128 in a ring-shaped path.

In some embodiments, a doped region 1008 (e.g., a doped isolation region) having the first doping type is in the semiconductor substrate 102 along sidewalls of the DTI structure 118. Doped region 1008 laterally surrounds the SPAD 104 along the DTI structure 118. In some embodiments, doped region 1008 extends from the front side 102a to doped region 110. In some embodiments in which the STI structure 702 is disposed along the front side 102a, doped region 1008 extends between the STI structure 702 and the DTI structure 118.

In some embodiments, an anti-reflection layer 1010 is under dielectric layer 122 and conductive grid structure 124. Further, a micro-lens 1012 is under the anti-reflection layer 1010.

FIG. 11 illustrates a cross-sectional view 1100 of some other embodiments of the image sensor integrated chip of FIG. 1.

In some embodiments, doped region 128 is under and surrounds sides of doped region 108. In some embodiments, an absorption enhancement structure 1102 is disposed along the back side 102b of the semiconductor substrate 102. For example, the absorption enhancement structure 1102 is formed by a pattern of sidewalls and surfaces of the semiconductor substrate 102 along the back side 102b of the semiconductor substrate 102.

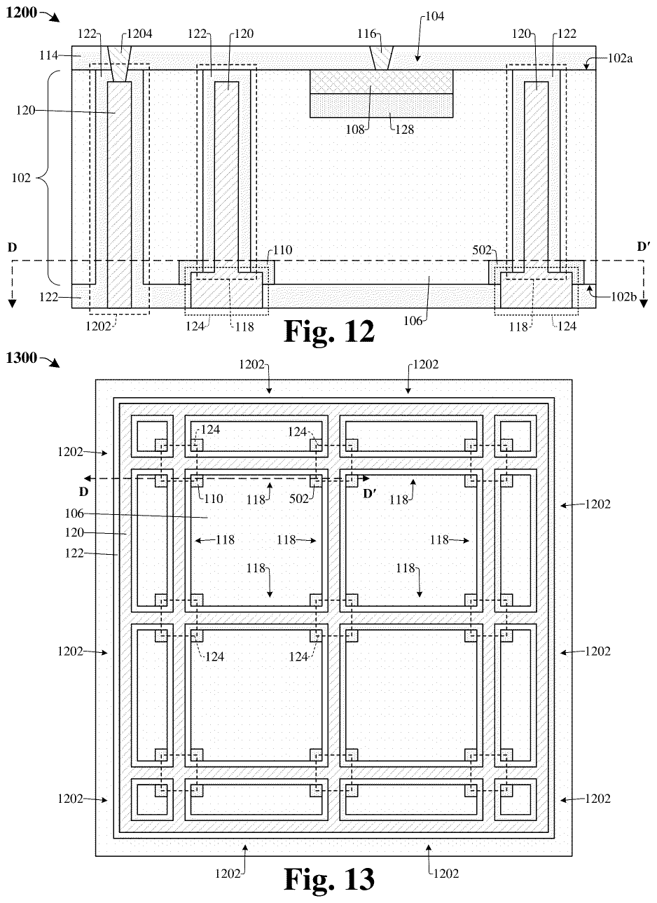

FIG. 12 illustrates a cross-sectional view 1200 and FIG. 13 illustrates a top view 1300 of some embodiments of the image senor integrated chip of FIG. 1 in which a conductive grounding structure 1202 surrounds the SPAD 104. In some embodiments, section line D-D′ of FIG. 13 corresponds to section line D-D′ of FIG. 12.

The conductive grounding structure 1202 surrounds the SPAD 104 and neighboring SPADs (not labeled) in an array of SPADs in a ring-shaped path. The conductive grounding structure 1202 includes (e.g., is formed by) conductive layer 120 and dielectric layer 122. Dielectric layer 122 is between conductive layer 120 and the semiconductor substrate 102 along the conductive grounding structure 1202. A contact 1204 is over and coupled to the conductive grounding structure 1202. The contact 1204 extends through dielectric layer 114 and dielectric layer 122 to conductive layer 120 at the conductive grounding structure 1202. A voltage can be provided to the second doped region 110 and the bulk region 106 through contact 1204 and conductive layer 120. For example, the bulk region 106 can be grounded by coupling contact 1204 to ground.

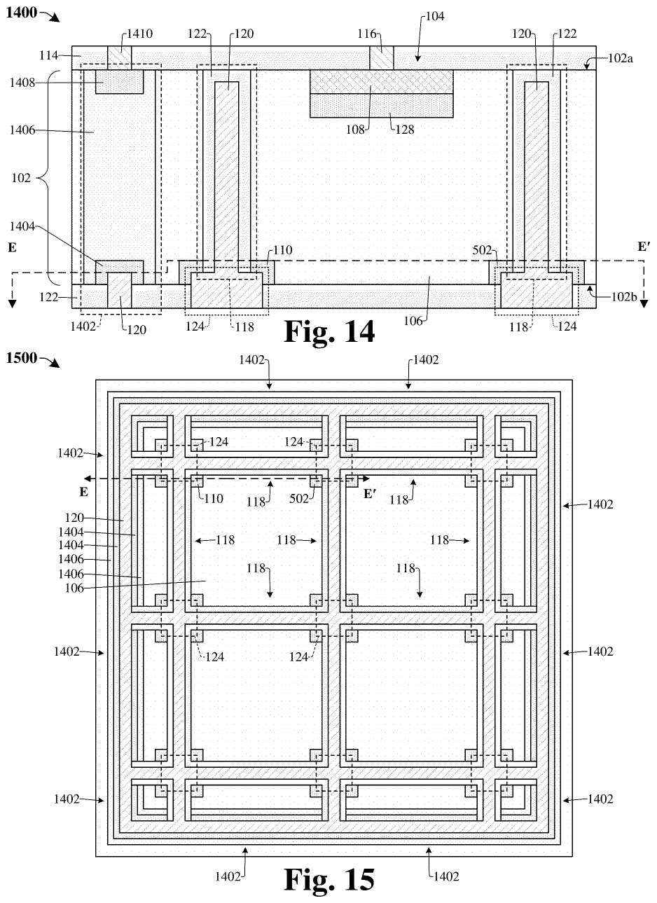

FIG. 14 illustrates a cross-sectional view 1400 and FIG. 15 illustrates a top view 1500 of some other embodiments of the image senor integrated chip of FIG. 1 in which a conductive grounding structure 1402 surrounds the SPAD 104. In some embodiments, section line E-E′ of FIG. 15 corresponds to section line E-E′ of FIG. 14.

Conductive grounding structure 1402 surrounds the SPADs of the array in a ring-shaped path. The conductive grounding structure 1402 includes a portion of conductive layer 120 that is disposed along the back side 102b of the semiconductor substrate 102. The conductive grounding structure 1402 further includes a doped region 1404 in the semiconductor substrate 102 along the conductive layer 120. The conductive grounding structure 1402 further includes a doped region 1408 in the semiconductor substrate 102 along the front side 102a. The conductive grounding structure 1402 further includes a doped region 1406 in the semiconductor substrate 102 that extends from doped region 1408 to doped region 1404. Doped region 1406, doped region 1404, and doped region 1408 have the first doping type. Doped region 1408 is coupled to doped region 1406, doped region 1404, and conductive layer 120 (which is coupled to the bulk region 106 by doped region 110). A contact 1410 contacts the semiconductor substrate 102 at doped region 1408. Thus, a voltage can be provided to the bulk region 106 through contact 1410.

In some embodiments, the doped region 1406 has a greater doping concentration than the bulk region 106. In some embodiments, doped region 1404 and doped region 1408 have greater doping concentrations than doped region 1406.

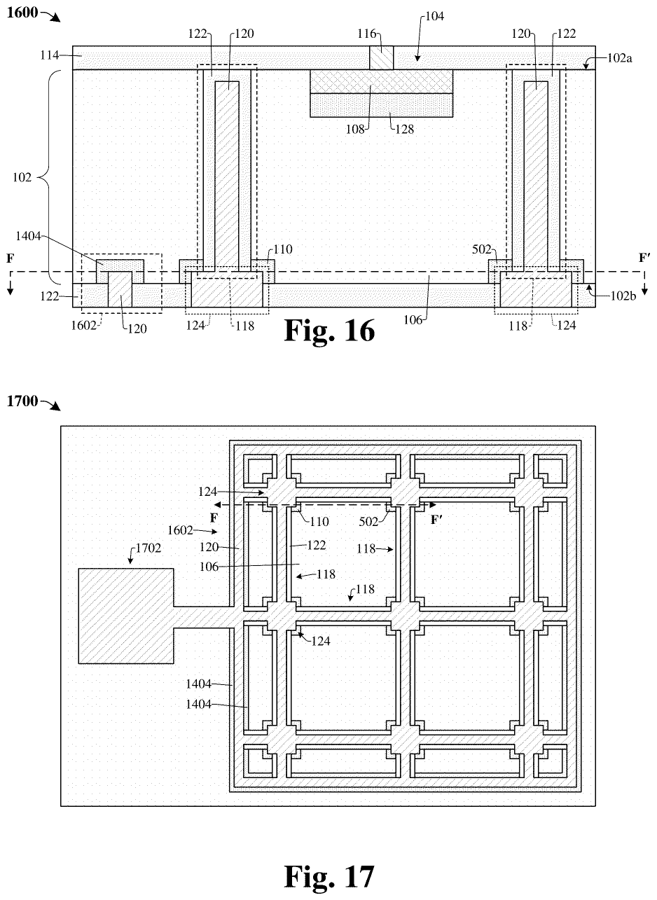

FIG. 16 illustrates a cross-sectional view 1600 and FIG. 17 illustrates a top view 1700 of some other embodiments of the image senor integrated chip of FIG. 1 in which a conductive grounding structure 1602 surrounds the SPAD 104. In some embodiments, section line F-F′ of FIG. 17 corresponds to section line F-F′ of FIG. 16.

Conductive grounding structure 1602 surrounds the SPADs of the array in a ring-shaped path. The conductive grounding structure 1602 includes the portion of conductive layer 120 that is disposed along the back side 102b of the semiconductor substrate 102. The conductive grounding structure 1602 further includes doped region 1404. A conductive pad 1702 is disposed along the back side 102b of the semiconductor substrate 102 and coupled to conductive layer 120. Thus, a voltage can be provided to the bulk region 106 through the conductive pad 1702. In some embodiments, the conductive pad 1702 is formed by conductive layer 120.

Although FIG. 13, FIG. 15, and FIG. 17 illustrate the conductive grid structure 124 as being under the DTI structure 118 at the “crossroads” of the DTI structure 118 but not between the “crossroads” of the DTI structure 118 (and the integrated chip includes doped region 502 separate from doped region 110), it will be appreciated that in some embodiments, the conductive grid structure 124 can be under the DTI structure 118 at the “crossroads” of the DTI structure 118 and between the “crossroads” of the DTI structure 118 (and doped region 110 laterally surrounds the SPAD 104 in a closed loop, as illustrated in FIG. 3 and FIG. 4) in the embodiments illustrated in FIG. 13, FIG. 15, and FIG. 17.

FIGS. 18, 19, 20, 21A, 21B, 22A, 22B, 23A, 23B, 24A, 24B, 25A, 25B, 26A, 26B, 27, 28, and 29 (referred to as FIGS. 18-29) illustrate cross-sectional views of some embodiments of a method of forming an image sensor integrated chip comprising a single photon avalanche diode (SPAD) in a semiconductor substrate, the SPAD including a first terminal along a front side of the semiconductor substrate and a second terminal along a back side of the semiconductor substrate. Although FIGS. 18-29 are described in relation to a method, it will be appreciated that the structures disclosed in FIGS. 18-29 are not limited to such a method, but instead may stand alone as structures independent of the method.

As shown in cross-sectional view 1800 of FIG. 18, a doped region 108 and a doped region 128 are formed in the semiconductor substrate 102 along the front side 102a of the semiconductor substrate 102. Bulk region 106 and doped region 128 have the first doping type. Doped region 108 has the second doping type. In some embodiments, doped regions 108, 128 are formed by separate ion implantation processes or some other suitable processes.

In some embodiments (e.g., corresponding to FIG. 7), a shallow trench isolation (STI) structure 702 is formed in the semiconductor substrate 102 along the front side 102a and laterally surrounding the SPAD 104. In some embodiments, forming the STI structure 702 comprises etching the semiconductor substrate 102 from the front side 102a toward the back side 102b to form an STI trench in the semiconductor substrate 102, and depositing a dielectric layer 704 in the STI trench. In some embodiments, dielectric layer 704 comprises silicon dioxide or some other suitable material and is deposited by a chemical vapor deposition (CVD) process, a physical vapor deposition (PVD) process, an atomic layer deposition (ALD) process, or some other suitable process. Although FIGS. 19-29 illustrate some embodiments of the method in which STI structure 702 is not formed along the front side 102a of the semiconductor substrate 102, it will be appreciated that in some embodiments, a similar method can be performed with STI structure 702 formed along the front side 102a.

In some embodiments (e.g., corresponding to FIG. 10), a doped region (e.g., doped region 1006 of FIG. 10) having the second doping type is formed in the semiconductor substrate 102 along the front side 102a. In some embodiments (e.g., corresponding to FIG. 10), a doped region (e.g., doped region 1008 of FIG. 10) having the first doping type is formed in the semiconductor substrate 102 around doped regions 108, 128. In some embodiments (e.g., corresponding to FIG. 11), doped region 128 is formed under and surrounding sides of doped region 108.

In some embodiments (e.g., corresponding to FIG. 14 and FIG. 15), a doped region 1406 and a doped region 1408 are formed in the semiconductor substrate 102. Doped region 1406 and doped region 1408 have the first doping type and are formed by ion implantation or some other suitable process.

As shown in cross-sectional view 1900 of FIG. 19, a dielectric layer 114 and contact 116 are formed on the front side 102a of the semiconductor substrate 102. In some embodiments, dielectric layer 114 comprises silicon dioxide or some other suitable material and is deposited by a CVD process, a PVD process, an ALD process, or some other suitable process. In some embodiments, contact 116 comprises copper, tungsten, aluminum, tantalum, or some other suitable material and is deposited by a CVD process, a PVD process, an ALD process or some other suitable process.

In some embodiments (e.g., corresponding to FIG. 14 and FIG. 15), a contact 1410 is formed on the back side 102b of the semiconductor substrate 102 and contacting doped region 1408. In some embodiments, contact 1410 comprises copper, tungsten, aluminum, tantalum, or some other suitable material and is deposited by a CVD process, a PVD process, an ALD process or some other suitable process.

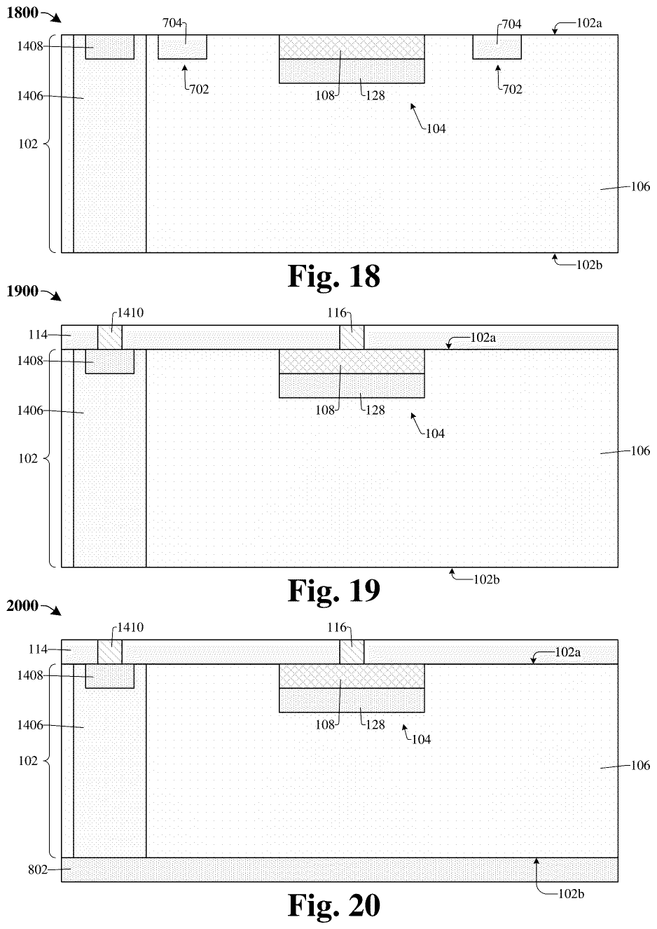

As shown in cross-sectional view 2000 of FIG. 20, in some embodiments (e.g., corresponding to FIG. 8 and FIG. 9), a semiconductor layer 802 having the first doping type is formed on the back side 102b of the semiconductor substrate 102. In some embodiments, the semiconductor layer 802 comprises silicon or some other suitable material and is deposited by an epitaxial growth process or some other suitable process.

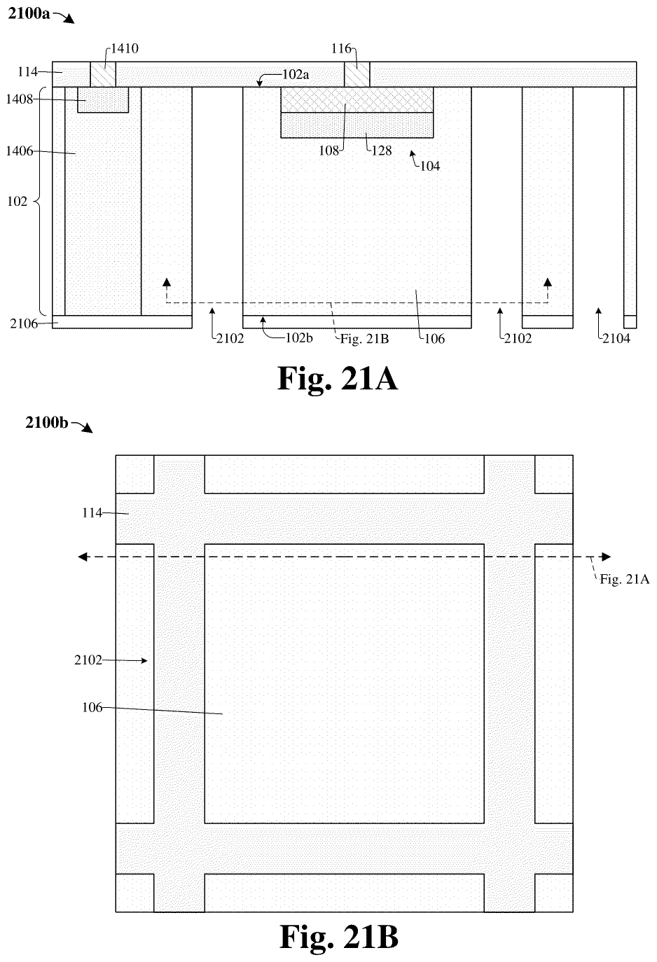

In some other embodiments, semiconductor layer 802 is not deposited on the back side 102b and the method proceeds to FIG. 21A and FIG. 21B. Although FIGS. 21A-29 illustrate some embodiments of the method in which semiconductor layer 802 is not deposited on the back side 102b of the semiconductor substrate 102, it will be appreciated that in some embodiments, a similar method can be performed with semiconductor layer 802 deposited on the back side 102b.

As shown in cross-sectional view 2100a of FIG. 21A and top view 2100b of FIG. 21B, the semiconductor substrate 102 is etched from the back side 102b toward the front side 102a to form a deep trench isolation (DTI) trench 2102 in the semiconductor substrate 102. The DTI trench 2102 is delimited by sidewalls of the semiconductor substrate 102. In some embodiments, a masking layer 2106 is formed along the back side 102b of the semiconductor substrate 102 and the etching is performed according to the masking layer 2106. In some embodiments, the masking layer is or comprises a photoresist mask layer, a hard mask layer, or some other suitable layer. In some embodiments, the etching comprises a dry etching process such as, for example, a plasma etching process, a reactive ion etching process, an ion beam etching process, or some other suitable process.

In some embodiments, the etching extends through the semiconductor substrate 102 to the front side 102a, and the DTI trench 2102 is further delimited by a surface of dielectric layer 114. In some other embodiments (e.g., corresponding to FIG. 7), the etching extending into the semiconductor substrate 102 but not through the semiconductor substrate 102 to the front side 102a, and the DTI trench 2102 is further delimited by a lower surface of the semiconductor substrate 102. In such embodiments, the DTI trench 2102 is directly under the STI structure 702.

In some embodiments (e.g., corresponding to FIG. 12 and FIG. 13), the semiconductor substrate 102 is further etched from the back side 102b toward the front side 102a to form a grounding trench 2104 in the semiconductor substrate 102. In some embodiments (e.g., corresponding to FIG. 8), the etching extends through semiconductor layer 802 into the semiconductor substrate 102. In some embodiments (e.g., corresponding to FIG. 11), an absorption enhancement structure 1102 is formed along the back side 102b of the semiconductor substrate 102 before the DTI trench 2102 is formed.

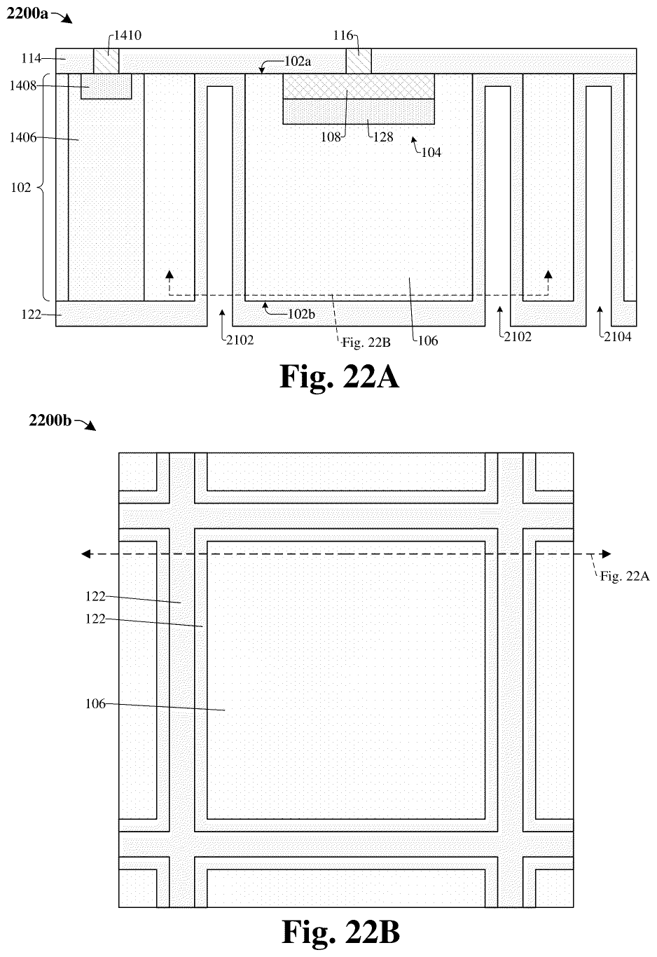

As shown in cross-sectional view 2200a of FIG. 22A and top view 2200b of FIG. 22B, a dielectric layer 122 is deposited in the DTI trench 2102 (e.g., on sidewalls the semiconductor substrate 102) and on the back side 102b of the semiconductor substrate 102. In some embodiments, dielectric layer 122 comprises silicon dioxide or some other suitable material and is deposited by a CVD process, a PVD process, an ALD process, or some other suitable process. In some embodiments (e.g., corresponding to FIG. 12 and FIG. 13), the dielectric layer 122 is deposited in the grounding trench 2104.

In some embodiments (e.g., corresponding to FIG. 10 and/or FIG. 11), a dielectric liner layer (e.g., dielectric liner layer 1002 of FIG. 10 and FIG. 11) is deposited in the DTI trench 2102 and on the back side 102b of the semiconductor substrate 102 before dielectric layer 122 is deposited. In some embodiments, dielectric liner layer comprises silicon oxide, aluminum oxide, hafnium oxide, tantalum oxide, or some other suitable material and is deposited by a CVD process, a PVD process, an ALD process, or some other suitable process.

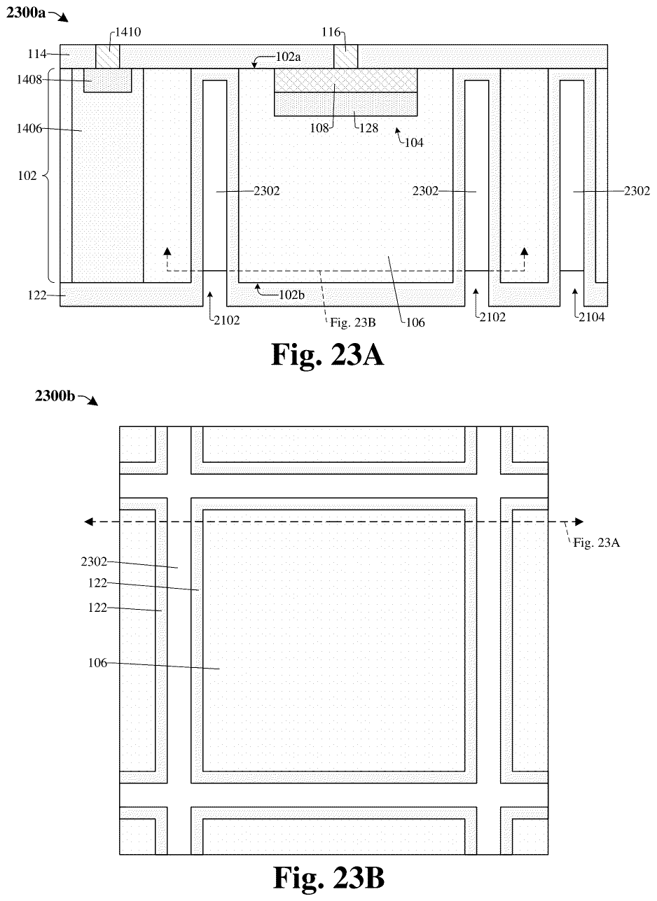

As shown in cross-sectional view 2300a of FIG. 23A and top view 2300b of FIG. 23B, a masking layer 2302 is formed in the DTI trench 2102 and the masking layer is recessed so that a bottom surface of the masking layer 2302 is set back from the back side 102b of the semiconductor substrate 102 (e.g., between sidewalls of the semiconductor substrate 102). In some embodiments, the masking layer is or comprises a photoresist masking layer. In some embodiments, the masking layer is recessed by an etching process or some other suitable process. In some embodiments, the masking layer 2302 is formed in the grounding trench 2104.

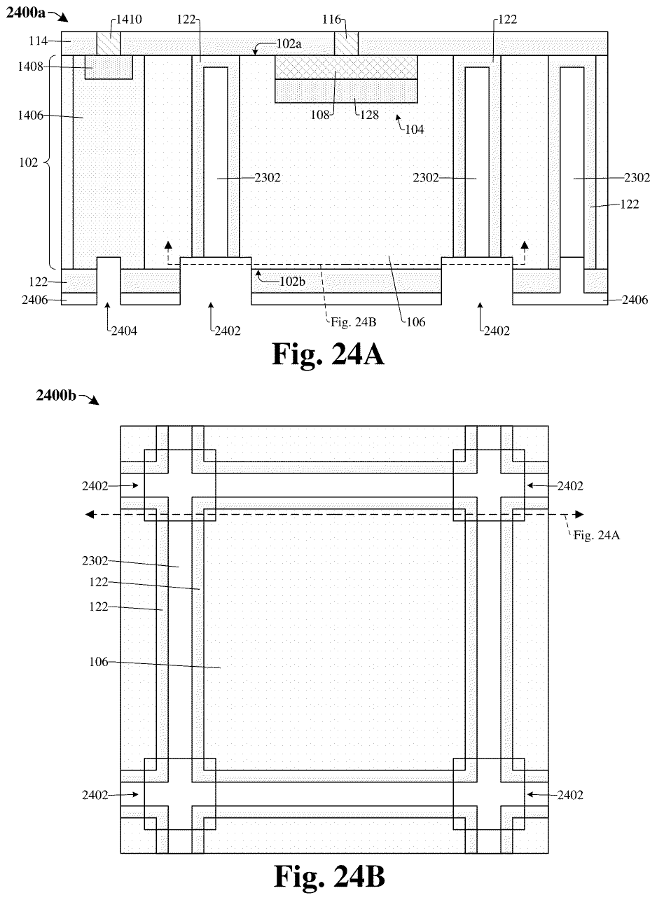

As shown in cross-sectional view 2400a of FIG. 24A and top view 2400b of FIG. 24B, dielectric layer 122 and the semiconductor substrate 102 are etched to form a grid trench 2402 in dielectric layer 122 and the semiconductor substrate 102 along the back side 102b. The grid trench 2402 is directly under the DTI trench 2102. The grid trench 2402 is delimited by sidewalls of dielectric layer 122, sidewalls of the semiconductor substrate 102, lower surfaces of the semiconductor substrate 102, and lower surfaces of dielectric layer 122. In some embodiments, a masking layer 2406 is formed along dielectric layer 122 and the etching is performed according to masking layer 2406. The etching stops at the bottom surface of masking layer 2302. Thus, the position of the bottom surface of masking layer 2302 can set the depth of the grid trench 2402. In some embodiments, the etching comprises a dry etching process or some other suitable process. In some embodiments, the masking layer 2406 is or comprises a hard mask layer or some other suitable layer. In some embodiments, masking layer 2302 and masking layer 2406 are removed after the etching.

In some embodiments, the grid trench 2402 is formed under the DTI trench 2102 at the “crossroads” of the DTI trench 2102, but not between the “crossroads” of the DTI trench 2102. In some other embodiments (e.g., corresponding to FIG. 3 and FIG. 4), the grid trench 2402 is formed under the DTI trench 2102 at the “crossroads” of the DTI trench 2102 and between the “crossroads” of the DTI trench 2102.

In some embodiments (e.g., corresponding to FIG. 12 and FIG. 13), masking layer 2406 is formed in and covering the grounding trench 2104. In some embodiments (e.g., corresponding to FIG. 14, FIG. 15, FIG. 16, and FIG. 17), dielectric layer 122 and the semiconductor substrate 102 are etched to form a grounding trench 2404 in dielectric layer 122 and in the semiconductor substrate 102 along the back side 102b. In some embodiments (e.g., corresponding to FIG. 14 and FIG. 15), the etching extends into doped region 1406.

In some embodiments (e.g., corresponding to FIG. 8), the etching extends into semiconductor layer 802 and thus the grid trench is delimited by sidewalls and upper surfaces of semiconductor layer 802.

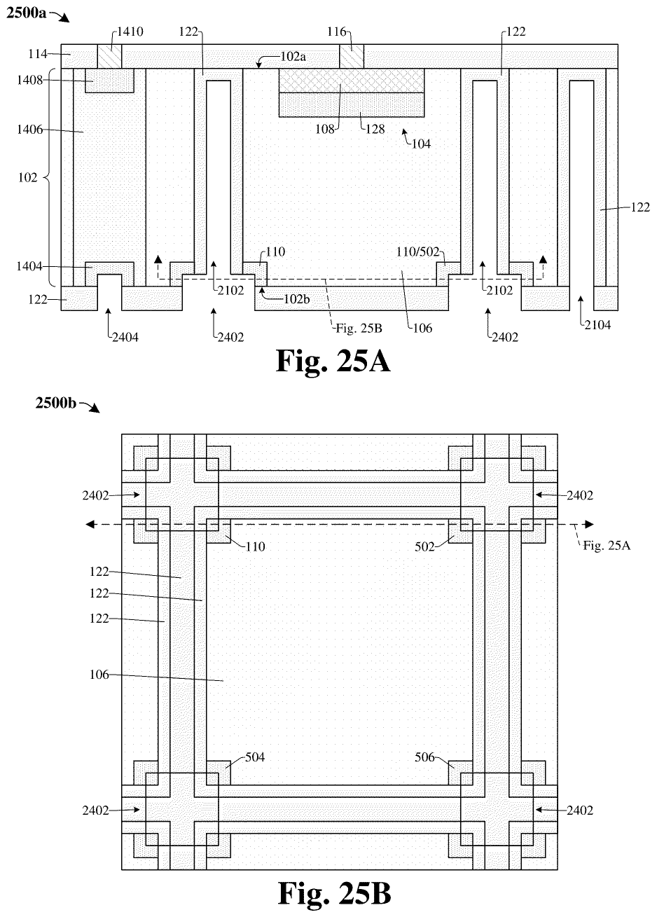

As shown in cross-sectional view 2500a of FIG. 25A and top view 2500b of FIG. 25B, doped region 110 is formed in the semiconductor substrate 102 along the sidewalls and lower surfaces of the semiconductor substrate 102 that delimit the grid trench 2402 (e.g., the sidewalls and lower surfaces of the semiconductor substrate 102 that are “exposed”). In some embodiments, doped region 110 is formed by an ion implantation process or some other suitable process.

In some embodiments, doped region 110 is disposed along one “corner” of the portion of the bulk region 106 and doped regions 502, 504, 506 are formed in the semiconductor substrate 102 along other corners of the portion of the bulk region 106. In some other embodiments (e.g., corresponding to FIG. 3 and FIG. 4), doped region 110 laterally surrounds a portion of the bulk region 106 in a ring-shaped path.

In some embodiments (e.g., corresponding to FIG. 14, FIG. 15, FIG. 16, and FIG. 17), doped region 1404 is formed in the semiconductor substrate 102 along the sidewalls and lower surface(s) of the semiconductor substrate 102 that delimit grounding trench 2404.

In some embodiments in which the semiconductor layer is on the back side 102b of the semiconductor substrate 102 (e.g., corresponding to FIG. 8), the implantation of doped region 110 can be omitted.

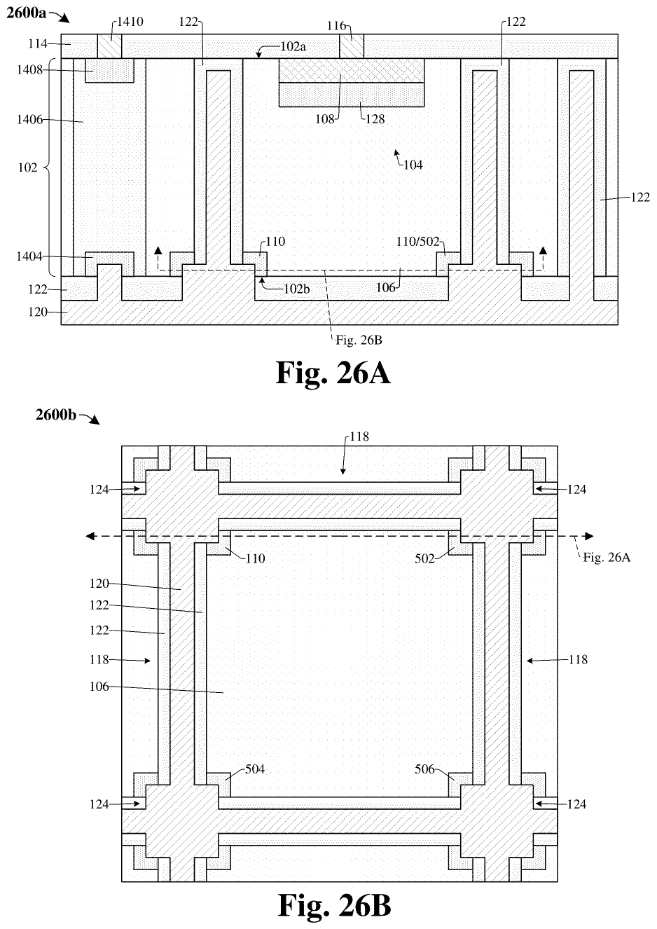

As shown in cross-sectional view 2600a of FIG. 26A and top view 2600b of FIG. 26B, a conductive layer 120 is deposited on dielectric layer 122 in the DTI trench 2102 to form the conductive core of the DTI structure 118, and on the semiconductor substrate 102 (e.g., on doped region 110) in the grid trench 2402 to form the conductive grid structure 124. In some embodiments, conductive layer 120 comprises copper, tungsten, aluminum, tantalum, titanium, or some other suitable material and is deposited by a CVD process, a PVD process, an ALD process, or some other suitable process.

In some embodiments (e.g., corresponding to FIG. 10 and FIG. 11), a conductive liner layer (e.g., conductive liner layer 1004 of FIG. 10 and FIG. 11) is deposited before conductive layer 120. In some embodiments, the conductive liner layer comprises tantalum nitride, titanium nitride, or some other suitable material. In some embodiments, the conductive liner layer improves the adhesion of conductive layer 120 to the underlying layers.

In some embodiments (e.g., corresponding to FIG. 12 and FIG. 13), conductive layer 122 is deposited in grounding trench 2104 to form conductive grounding structure 1202. In some embodiments (e.g., corresponding to FIG. 14, FIG. 15, FIG. 16, and FIG. 17), conductive layer 120 is deposited in grounding trench 2404 to form conductive grounding structure 1402 or conductive grounding structure 1602.

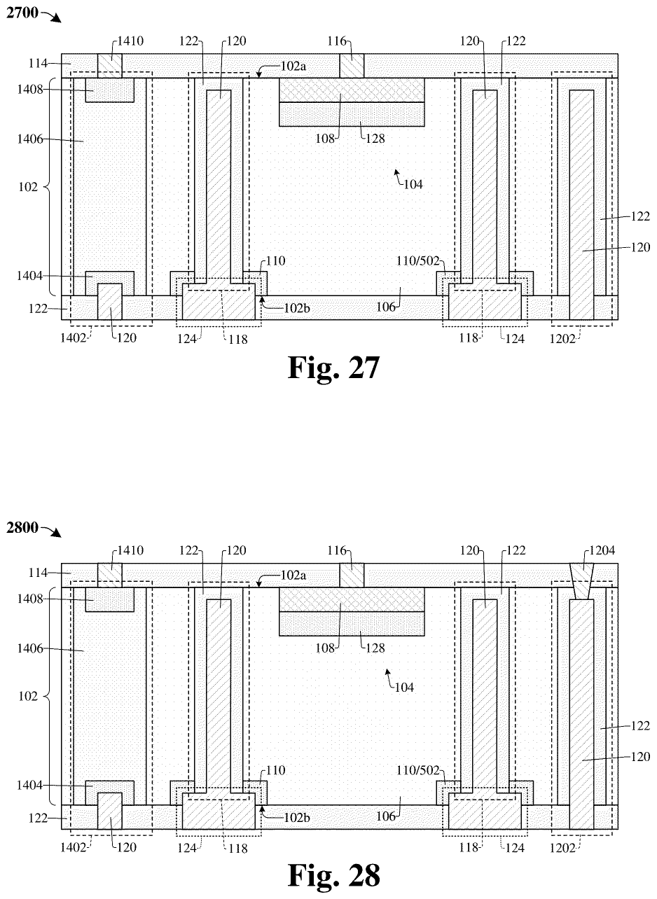

As shown in cross-sectional view 2700 of FIG. 27, a planarization process is performed on conductive layer 120 to remove the portion of conductive layer 120 that is on the bottom surface of dielectric layer 122. The planarization process further delimits the conductive grid structure 124 and the grounding structure (e.g., 1202, 1402, or 1602). In some embodiments, the planarization process is or comprises a chemical mechanical planarization (CMP) or some other suitable process.

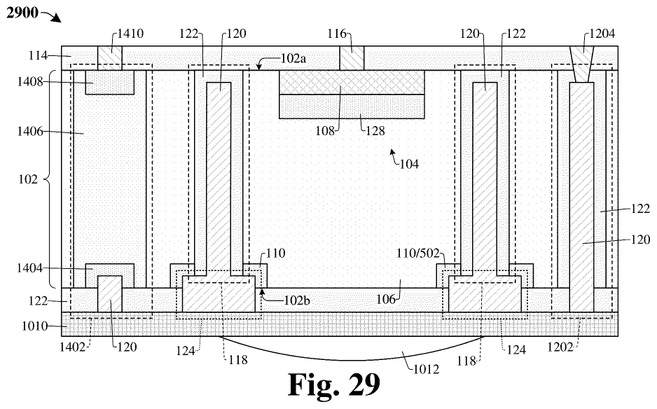

As shown in cross-sectional view 2800 of FIG. 28, in some embodiments (e.g., corresponding to FIG. 12 and FIG. 13), a contact 1204 is formed on conductive layer 120 at conductive grounding structure 1202. In some embodiments, contact 1204 is formed by etching dielectric layer 114 and dielectric layer 122 and depositing contact 1204 on conductive layer 120. In some embodiments, contact 1204 comprises copper, tungsten, aluminum, tantalum, titanium, or some other suitable material.

As shown in cross-sectional view 2900 of FIG. 29, an anti-reflective layer 1010 is formed over dielectric layer 122 and a micro-lens 1012 is formed over the anti-reflective layer 1010.

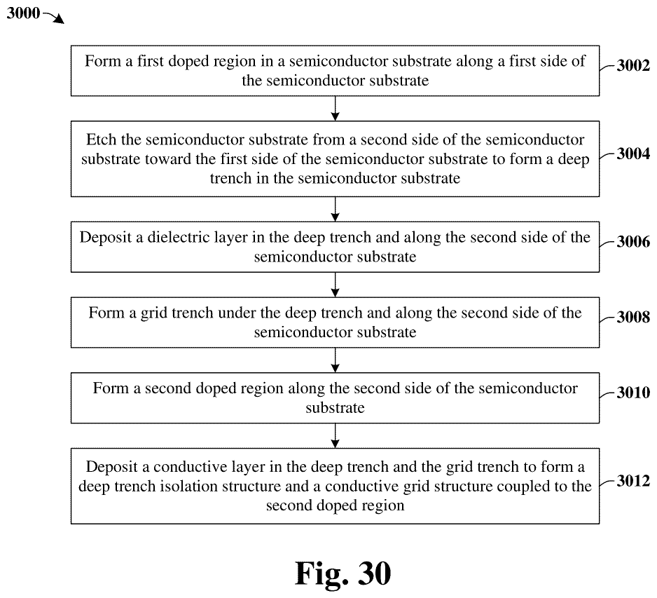

FIG. 30 illustrates a flow diagram of some embodiments of a method 3000 of forming an image sensor integrated chip comprising a single photon avalanche diode (SPAD) in a semiconductor substrate, the SPAD including a first doped region along a first side of the semiconductor substrate and a second doped region along a second side of the semiconductor substrate. While method 3000 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 3002, form a first doped region in a semiconductor substrate along a first side of the semiconductor substrate. For example, the first doped region (e.g., cathode) is formed in the semiconductor substrate along the front side of the semiconductor substrate. A bulk region of the semiconductor substrate has a first doping type. The first doped region has a second doping type different than the first doping type. FIG. 18 illustrates a cross-sectional view 1800 of some embodiments corresponding to block 3002.

At block 3004, etch the semiconductor substrate from a second side of the semiconductor substrate toward the first side of the semiconductor substrate to form a deep trench in the semiconductor substrate. FIG. 21A illustrates a cross-sectional view 2100a of some embodiments corresponding to block 3004.

At block 3006, deposit a dielectric layer in the deep trench and along the second side of the semiconductor substrate. FIG. 22A illustrates a cross-sectional view 2200a of some embodiments corresponding to block 3006.

At block 3008, form a grid trench under the deep trench and along the second side of the semiconductor substrate. For example, in some embodiments, the dielectric layer and the semiconductor substrate are etched from a back side of the semiconductor substrate toward the front side to form the grid trench in the semiconductor substrate under the deep trench. In some other embodiments, the dielectric layer and a semiconductor layer are etched to form the grid trench in the semiconductor layer. The semiconductor layer is on the back side of the semiconductor substrate and has the first doping type. FIG. 24A illustrates a cross-sectional view 2400a of some embodiments corresponding to block 3008.

At block 3010, form a second doped region along the second side of the semiconductor substrate. For example, the second doped region (e.g., anode) having the first doping type is formed in the semiconductor substrate along the grid trench. In some embodiments, the semiconductor layer having the first doping type is formed (e.g., instead of the second doped region) on the back side of the semiconductor substrate before the deep trench and the grid trench are formed. FIG. 25A illustrates a cross-sectional view 2500a of some embodiments corresponding to block 3010.

At block 3012, deposit a conductive layer in the deep trench and the grid trench to form a deep trench isolation structure and a conductive grid structure coupled to the second doped region. FIG. 26A illustrates a cross-sectional view 2600a of some embodiments corresponding to block 3012.

Thus, the present disclosure relates to an image sensor integrated chip comprising a single photon avalanche diode (SPAD) in a semiconductor substrate, the SPAD including a first terminal along a front side of the semiconductor substrate and a second terminal along a back side of the semiconductor substrate, the second terminal coupled to a deep trench isolation (DTI) structure and a conductive grid structure along the back side of the semiconductor substrate.

Accordingly, in some embodiments, the present disclosure relates to an integrated chip. The integrated chip includes a semiconductor substrate including a bulk region having a first doping type. The integrated chip includes a first doped region in the semiconductor substrate along a first side of the semiconductor substrate and having a second doping type, different than the first doping type. The first doped region forms a first terminal of a single photon avalanche diode (SPAD). The integrated chip includes a conductive layer extending from a second side of the semiconductor substrate toward the first side of the semiconductor substrate and laterally surrounding the SPAD. The conductive layer has a first sidewall, a second sidewall, and an upper surface extending from a bottom of the first sidewall of the conductive layer to a top of the second sidewall of the conductive layer. The integrated chip includes a dielectric layer between the first sidewall of the conductive layer and a first sidewall of the semiconductor substrate. The integrated chip includes a second terminal of the SPAD along the second side of the semiconductor substrate. The second terminal has the first doping type and is coupled to the conductive layer along the upper surface of the conductive layer and the second sidewall of the conductive layer.

In other embodiments, the present disclosure relates to a method of forming an integrated chip. The method includes forming a first doped region in a semiconductor substrate along a first side of the semiconductor substrate. The semiconductor substrate includes a bulk region having a first doping type. The first doped region has a second doping type different than the first doping type. The method includes etching the semiconductor substrate from a second side of the semiconductor substrate, opposite the first side, toward the first side to form a deep trench in the semiconductor substrate. The deep trench is delimited by a first sidewall of the semiconductor substrate. The method includes depositing a dielectric layer in the deep trench and along the first sidewall of the semiconductor substrate. The method includes etching the dielectric layer and the semiconductor substrate from the second side of the semiconductor substrate toward the first side to form a grid trench in the semiconductor substrate and under the deep trench. The grid trench is delimited by a second sidewall of the semiconductor substrate and a lower surface of the semiconductor substrate that extends from a top of the second sidewall to a bottom of the first sidewall of the semiconductor substrate. The method includes forming a second doped region in the semiconductor substrate along the second sidewall and the lower surface of the semiconductor substrate. The second doped region has the first doping type. The method includes depositing a conductive layer in the deep trench along the dielectric layer and in the grid trench along the second sidewall and the lower surface of the semiconductor substrate so the conductive layer is coupled to the second doped region along the second sidewall and the lower surface of the semiconductor substrate.

In yet other embodiments, the present disclosure relates to a method of forming an integrated chip. The method includes forming a first doped region in a semiconductor substrate along a first side of the semiconductor substrate. The semiconductor substrate includes a bulk region having a first doping type. The first doped region has a second doping type, different than the first doping type. The first doped region forms a first terminal of a single photon avalanche diode (SPAD). The method includes forming a deep trench isolation (DTI) structure extending from a second side of the semiconductor substrate toward the first side of the semiconductor substrate and laterally surrounding the SPAD. The DTI structure includes a conductive core and a dielectric liner. The dielectric liner is between a sidewall of the conductive core and a first sidewall of the semiconductor substrate. The method includes forming a conductive grid structure under the DTI structure and coupled to the conductive core. The conductive grid structure has a sidewall and an upper surface. The upper surface extends from a top of the sidewall of the conductive grid structure to a bottom of the sidewall of the conductive core of the DTI structure. The method includes forming a second terminal of the SPAD along the second side of the semiconductor substrate. The second terminal has the first doping type and is coupled to the conductive grid structure along the upper surface of the conductive grid structure and the sidewall of the conductive grid structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip, comprising:
a semiconductor substrate including a bulk region having a first doping type;
a first doped region in the semiconductor substrate along a first side of the semiconductor substrate and having a second doping type, different than the first doping type, the first doped region forming a first terminal of a single photon avalanche diode (SPAD);
a conductive layer extending from a second side of the semiconductor substrate toward the first side of the semiconductor substrate and laterally surrounding the SPAD, the conductive layer having a first sidewall, a second sidewall, and an upper surface extending from a bottom of the first sidewall of the conductive layer to a top of the second sidewall of the conductive layer;
a dielectric layer between the first sidewall of the conductive layer and a first sidewall of the semiconductor substrate; and
a second terminal of the SPAD along the second side of the semiconductor substrate, wherein the second terminal has the first doping type and is coupled to the conductive layer along the upper surface of the conductive layer and the second sidewall of the conductive layer.

2. The integrated chip of claim 1, further comprising:
a second doped region in the semiconductor substrate along the second side of the semiconductor substrate and having the first doping type, wherein the second doped region forms the second terminal of the SPAD and is coupled to the conductive layer along the upper surface of the conductive layer and the second sidewall of the conductive layer.

3. The integrated chip of claim 2, wherein the semiconductor substrate has a second sidewall and a lower surface, the lower surface of the semiconductor substrate extending from a bottom of the first sidewall of the semiconductor substrate to a top of the second sidewall of the semiconductor substrate, wherein the second doped region extends along the lower surface and the second sidewall of the semiconductor substrate, wherein the upper surface of the conductive layer contacts the lower surface of the semiconductor substrate, and wherein the second sidewall of the conductive layer contacts the second sidewall of the semiconductor substrate.

4. The integrated chip of claim 2, further comprising:
a third doped region in the semiconductor substrate along the second side of the semiconductor substrate and laterally spaced from the second doped region, the third doped region having the first doping type, the third doped region coupled to the conductive layer.

5. The integrated chip of claim 2, wherein the second doped region laterally surrounds the SPAD and has a ring-shaped top layout.

6. The integrated chip of claim 1, further comprising:
a semiconductor layer on the second side of the semiconductor substrate and having the first doping type, wherein the semiconductor layer forms the second terminal of the SPAD and is coupled to the conductive layer along the upper surface of the conductive layer and the second sidewall of the conductive layer.

7. The integrated chip of claim 1, further comprising:
a conductive contact along the first side of the semiconductor substrate and coupled to the conductive layer.

8. The integrated chip of claim 1, further comprising:
a second doped region in the semiconductor substrate along the second side of the semiconductor substrate and having the first doping type, the second doped region coupled to the conductive layer;
a third doped region in the semiconductor substrate along the first side of the semiconductor substrate and having the first doping type;
a fourth doped region in the semiconductor substrate and having the first doping type, the fourth doped region extending from the third doped region to the second doped region; and
a conductive contact along the first side of the semiconductor substrate and coupled to the third doped region.

9. The integrated chip of claim 1, further comprising:
a conductive pad along the second side of the semiconductor substrate and coupled to the conductive layer.

10. A method of forming an integrated chip, the method comprising:
forming a first doped region in a semiconductor substrate along a first side of the semiconductor substrate, the semiconductor substrate including a bulk region having a first doping type, the first doped region having a second doping type different than the first doping type;
etching the semiconductor substrate from a second side of the semiconductor substrate, opposite the first side, toward the first side to form a deep trench in the semiconductor substrate, wherein the deep trench is delimited by a first sidewall of the semiconductor substrate;
depositing a dielectric layer in the deep trench and along the first sidewall of the semiconductor substrate;
etching the dielectric layer and the semiconductor substrate from the second side of the semiconductor substrate toward the first side to form a grid trench in the semiconductor substrate and under the deep trench, wherein the grid trench is delimited by a second sidewall of the semiconductor substrate and a lower surface of the semiconductor substrate that extends from a top of the second sidewall to a bottom of the first sidewall of the semiconductor substrate;
forming a second doped region in the semiconductor substrate along the second sidewall and the lower surface of the semiconductor substrate, the second doped region having the first doping type; and
depositing a conductive layer in the deep trench along the dielectric layer and in the grid trench along the second sidewall and the lower surface of the semiconductor substrate so the conductive layer is coupled to the second doped region along the second sidewall and the lower surface of the semiconductor substrate.

11. The method of claim 10, further comprising:
forming a third doped region in the semiconductor substrate along a third sidewall and a second lower surface of the semiconductor substrate, wherein the third doped region has the first doping type and is laterally spaced from the second doped region, and wherein the conductive layer is deposited along the third sidewall and the second lower surface of the semiconductor substrate so the conductive layer is coupled to the third doped region along the third sidewall and the second lower surface of the semiconductor substrate.

12. The method of claim 10, wherein the second doped region laterally surrounds the bulk region in closed path.

13. The method of claim 10, wherein the first doped region forms a first terminal of a single photon avalanche diode (SPAD), and wherein the second doped region forms a second terminal of the SPAD.

14. The method of claim 10, further comprising:
etching the semiconductor substrate from the second side of the semiconductor substrate toward the first side to form a grounding trench in the semiconductor substrate;
depositing the dielectric layer in the grounding trench;
depositing the conductive layer over the dielectric layer in the grounding trench; and
forming a conductive contact along the first side of the semiconductor substrate and extending through the dielectric layer to the conductive layer at the grounding trench.

15. The method of claim 10, further comprising:
etching the dielectric layer and the semiconductor substrate from the second side of the semiconductor substrate toward the first side to form a grounding trench in the semiconductor substrate along the second side of the semiconductor substrate, wherein the grounding trench is delimited by a second lower surface of the semiconductor substrate;
forming a third doped region in the semiconductor substrate along the second lower surface of the semiconductor substrate, the third doped region having the first doping type; and
depositing the conductive layer in the grounding trench and on the second lower surface of the semiconductor substrate so the conductive layer is coupled to the third doped region along the second lower surface of the semiconductor substrate.

16. The method of claim 15, further comprising:
forming a fourth doped region in the semiconductor substrate along the first side of the semiconductor substrate, the fourth doped region having the first doping type;
forming a fifth doped region in the semiconductor substrate, the fifth doped region having the first doping type and extending from the fourth doped region to the third doped region; and
forming a conductive contact along the first side of the semiconductor substrate and contacting the fourth doped region.

17. The method of claim 15, further comprising:
forming a conductive pad along the second side of the semiconductor substrate and coupled to the conductive layer.

18. A method of forming an integrated chip, the method comprising:
forming a first doped region in a semiconductor substrate along a first side of the semiconductor substrate, the semiconductor substrate including a bulk region having a first doping type, the first doped region having a second doping type, different than the first doping type, the first doped region forming a first terminal of a single photon avalanche diode (SPAD);
forming a deep trench isolation (DTI) structure extending from a second side of the semiconductor substrate toward the first side of the semiconductor substrate and laterally surrounding the SPAD, the DTI structure comprising a conductive core and a dielectric liner, wherein the dielectric liner is between a sidewall of the conductive core and a first sidewall of the semiconductor substrate;
forming a conductive grid structure under the DTI structure and coupled to the conductive core, wherein the conductive grid structure has a sidewall and an upper surface, the upper surface extending from a top of the sidewall of the conductive grid structure to a bottom of the sidewall of the conductive core of the DTI structure; and
forming a second terminal of the SPAD along the second side of the semiconductor substrate, wherein the second terminal has the first doping type and is coupled to the conductive grid structure along the upper surface of the conductive grid structure and the sidewall of the conductive grid structure.

19. The method of claim 18, wherein forming the second terminal comprises forming a second doped region in the semiconductor substrate along the second side of the semiconductor substrate, wherein the second doped region has the first doping type and is coupled to the conductive grid structure along the upper surface of the conductive grid structure and the sidewall of the conductive grid structure.

20. The method of claim 18, wherein forming the second terminal comprises forming a semiconductor layer on the second side of the semiconductor substrate, wherein the semiconductor layer has the first doping type and is coupled to the conductive grid structure along the upper surface of the conductive grid structure and the sidewall of the conductive grid structure.
